(19) United States
(12) Patent Application Publication
(10) Pub. No.: US 2025/0304431 A1
(43) Pub. Date: Oct. 2, 2025

(54) ELECTRONIC DEVICE

(71) Applicant: Merry Electronics(Shenzhen) Co., Ltd., ShenZhen (CN)

(72) Inventors: Po Kai Chang, Taichung (TW); Yung-Hsiang Chang, Taichung (TW); Jia Yin Wu, Taichung (TW)

(73) Assignee: Merry Electronics(Shenzhen) Co., Ltd., ShenZhen (CN)

(21) Appl. No.: 18/646,772

(22) Filed: Apr. 26, 2024

(30) Foreign Application Priority Data
Mar. 28, 2024 (TW) 113111865

(51) Int. Cl. B81B 7/00; H01L 23/00; H01L 23/053; H01L 23/10; H01L 23/31; H01L 23/538

(52) U.S. Cl. CPC B81B 7/0064; H01L 23/053; H01L 23/10; H01L 23/3121; H01L 23/5386; H01L 24/48; H01L 2224/48137

(57) ABSTRACT

An electronic device includes a substrate, a package component, a spacer layer, a first sensor chip, first and second processing chips, and a gel. The substrate has upper and lower surfaces, a through hole, and a recess. The package component is disposed on the upper surface. The package component and the substrate define a first chamber. The spacer layer is disposed on the upper surface and covers the recess. The spacer layer and the recess define a second chamber. The first sensor chip is disposed on the upper surface, located in the first chamber, and covers the through hole. The first sensor chip is electrically connected to the first processing chip. The second processing chip is disposed in the recess and in the second chamber. The second processing chip is air isolated from the first chamber. The gel fills the second chamber and at least covers the second processing chip.

### CROSS-REFERENCE TO RELATED APPLICATION

This application claims the priority benefit of Taiwan application serial no. 113111865, filed on Mar. 28, 2024. The entirety of the above-mentioned patent application is hereby incorporated by reference herein and made a part of this specification.

### BACKGROUND

### Technical Field

The disclosure relates to an electronic device.

### Description of Related Art

In electronic devices, it is common to integrate a plurality of sensors into one package structure, which may lead to the difficulty of miniaturizing the package structure; besides, placing chips with different functions in the same chamber may easily cause interference between the chips (such as signal interference or thermal effects), thereby reducing the sensitivity of the sensors.

### SUMMARY

The disclosure provides an electronic device where a sensor chip and a processing chip are placed in different chambers, thereby reducing the interference caused by the processing chip to the sensor chip during operation and achieving improved sensor sensitivity.

According to an embodiment of the disclosure, an electronic device includes a substrate, a package component, a spacer layer, a first sensor chip, a first processing chip, a second processing chip, and a gel. The substrate has a first upper surface and a lower surface opposite to each other, a through hole penetrating the substrate and connecting the upper surface and the lower surface, and a recess extending from the upper surface to the lower surface. The package component is disposed on the upper surface of the substrate, and the package component and the substrate define a first chamber. The spacer layer is disposed on the upper surface of the substrate and covers the recess, and the spacer layer and the recess define a second chamber. The first sensor chip is disposed on the upper surface of the substrate, is located in the first chamber, and covered the through hole. The first sensor chip is electrically connected to a first processing chip. The second processing chip is disposed in the recess of the substrate and located in the second chamber, and the second processing chip is air isolated from the first chamber. The gel fills the second chamber and at least covers the second processing chip.

In an embodiment of the disclosure, the first processing chip is disposed on the upper surface of the substrate and adjacent to the first sensor chip and located in the first chamber.

In an embodiment of the disclosure, the first processing chip is disposed in the recess of the substrate and adjacent to the second processing chip and located in the second chamber, and the gel further covers the first processing chip.

In an embodiment of the disclosure, the spacer layer has a flat-shaped structure, a top surface facing the first chamber, and a bottom surface facing the second chamber.

In an embodiment of the disclosure, the electronic device further includes a second sensor chip that is disposed on the top surface, located in the first chamber, and electrically connected to the second processing chip through the substrate.

In an embodiment of the disclosure, the spacer layer further has an opening, and the gel completely fills the second chamber and covers the opening.

In an embodiment of the disclosure, the gel does not completely fill the second chamber, so that a gap is formed between the gel and the bottom surface, and the gel has a concave arc-shaped cross-sectional profile adjacent to the gap.

In an embodiment of the disclosure, the spacer layer includes a first portion having a first thickness and a second portion having a second thickness, and the first thickness is less than the second thickness.

In an embodiment of the disclosure, the first processing chip is disposed on the first portion of the spacer layer and adjacent to the first sensor chip and located in the first chamber, and the first sensor chip is electrically connected to the substrate through the spacer layer.

In an embodiment of the disclosure, the electronic device further includes a second sensor chip that is disposed on the second portion of the spacer layer and located in the first chamber. A portion of the second sensor chip is stacked on the first processing chip, and the second sensor chip is electrically connected to the second processing chip through the substrate.

In an embodiment of the disclosure, the first portion and the second portion jointly define that the spacer layer is in a stepped shape.

In an embodiment of the disclosure, the second portion surrounds the first portion, and the second portion and the first portion jointly form a recess of the spacer layer.

In an embodiment of the disclosure, the second portion further has an opening, and the gel completely fills the second chamber and covers the opening.

In an embodiment of the disclosure, the first processing chip is disposed in the recess of the substrate, stacked on the second processing chip, and located in the second chamber.

In an embodiment of the disclosure, the spacer layer includes a top portion and a side portion vertically connected to peripheries of the top portion, and the top portion and the side portion jointly define that the spacer layer is in an inverted U shape.

In an embodiment of the disclosure, the top portion further has an opening, and the gel completely fills the second chamber and covers the opening and the first processing chip.

In an embodiment of the disclosure, the gel does not completely fill the second chamber, so that a gap is formed between the gel and the top portion, and the gel has a convex arc-shaped cross-sectional profile adjacent to the gap.

In an embodiment of the disclosure, the electronic device further includes a plurality of bonding components, and the bonding components are disposed between the spacer layer and the upper surface of the substrate. The spacer layer is bonded to the substrate through the bonding components and is electrically connected to the substrate.

In an embodiment of the disclosure, the spacer layer includes at least one conductive path, and the first sensor chip is electrically connected to the first processing chip through the at least one conductive path of the spacer layer.

In an embodiment of the disclosure, the electronic device further includes a plurality of conductive components, and the conductive components are disposed on the lower surface of the substrate and electrically connected to the first processing chip and the second processing chip.

In view of the above, according to the design of the electronic device provided in one or more embodiments of the disclosure, the package component and the substrate define the first chamber, and the spacer layer and the recess of the substrate define the second chamber, where the first sensor chip is located in the first chamber, and the second processing chip is located in the second chamber and is air isolated from the first chamber. With this design, the sensor chip and the processing chip can be separately disposed in different chambers to reduce the interference caused by the processing chip to the sensor chip during operation, thereby allowing the electronic device provided in one or more embodiments of the disclosure to achieve improved sensor sensitivity.

In order to make the above-mentioned features and advantages of the disclosure comprehensible, embodiments accompanied with drawings are described in detail below.

### BRIEF DESCRIPTION OF THE DRAWINGS

The accompanying drawings, which are included to provide a further understanding of the disclosure, are incorporated in and constitute a part of this specification. The drawings illustrate embodiments of the disclosure and, together with the description, serve to explain the principles of the disclosure.

FIG. 1 is a schematic cross-sectional view of an electronic device according to an embodiment of the disclosure.

FIG. 2 is a schematic cross-sectional view of an electronic device according to another embodiment of the disclosure.

FIG. 3 is a schematic cross-sectional view of an electronic device according to another embodiment of the disclosure.

FIG. 4 is a schematic cross-sectional view of an electronic device according to another embodiment of the disclosure.

FIG. 5 is a schematic cross-sectional view of an electronic device according to another embodiment of the disclosure.

FIG. 6 is a schematic cross-sectional view of an electronic device according to another embodiment of the disclosure.

FIG. 7 is a schematic cross-sectional view of an electronic device according to another embodiment of the disclosure.

FIG. 8 is a cross-sectional schematic view of an electronic device according to another embodiment of the disclosure.

### DESCRIPTION OF THE EMBODIMENTS

The directional terminologies mentioned in the disclosure, such as “up,” “down,” “left,” “right,” “front,” “rear,” “top,” “bottom,” and so on, are used with reference to the accompanying drawings. Therefore, the directional terminologies are used for illustration and should not be construed as indication to absolute orientation in the disclosure.

The exemplary embodiments of the disclosure will be fully described below with reference to the drawings, but the disclosure may also be implemented in many different forms and should not be construed as being limited to the embodiments described herein. In the drawings, for clarity, a relative size, a thickness, and a location of each region, portion, and/or layer may not be necessarily drawn to scale and may be zoomed in. In the embodiments, the same or similar elements will be designated by the same or similar reference numerals, and descriptions thereof will be omitted. Furthermore, descriptions of well-known devices, methods, and materials may be omitted so as not to obscure the description of various principles of the disclosure.

It should be understood that, although the terminologies “first,” “second,” and so forth may serve to describe various elements, components, regions, layers, and/or sections in this disclosure, these elements, components, regions, layers, and/or sections shall not be limited by these terminologies. These terminologies merely serve to distinguish one element, component, region, layer, and/or section from another element, component, region, layer, or section.

Unless otherwise defined, all terminologies (including technical and scientific terminologies) used herein have the same meaning as commonly understood by people having ordinary skill in the art to which the disclosure belongs.

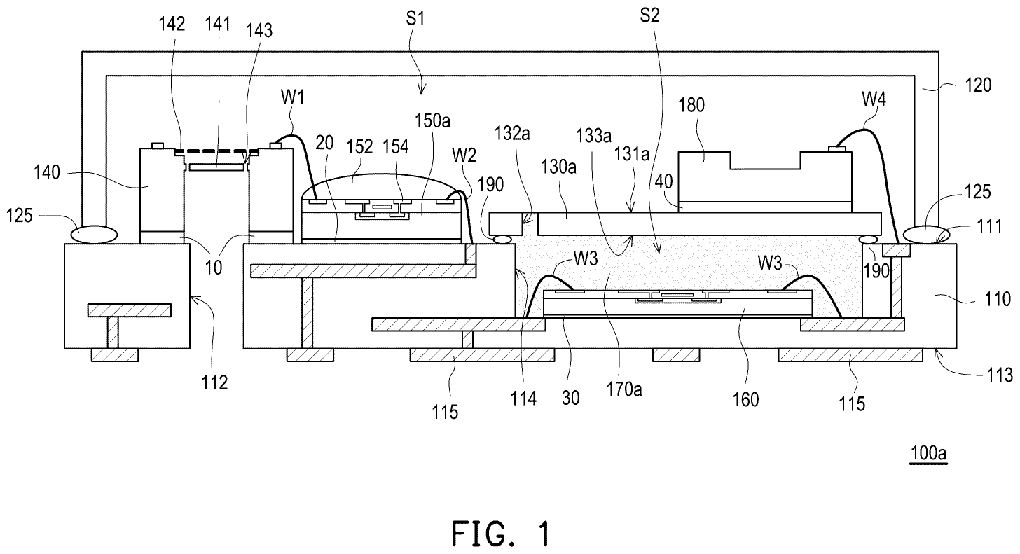

FIG. 1 is a schematic cross-sectional view of an electronic device according to an embodiment of the disclosure. With reference to FIG. 1, in this embodiment, an electronic device 100a includes a substrate 110, a package component 120, a spacer layer 130a, a first sensor chip 140, a first processing chip 150a, a second processing chip 160, and a gel 170a. The substrate 110 has an upper surface 111 and a lower surface 113 that are opposite to each other, a through hole 112 that penetrates the substrate 110 and connects the upper surface 111 and the lower surface 113, and a recess 114 that extends from the upper surface 111 to the lower surface 113. The package component 120 is disposed on the upper surface 111 of the substrate 110, and the package component 120 and the substrate 110 define a first chamber S1. The spacer layer 130a is disposed on the upper surface 111 of the substrate 110 and covers the recess 114, and the spacer layer 130a and the recess 144 define a second chamber S2. The first sensor chip 140 is disposed on the upper surface 111 of the substrate 110, is located in the first chamber S1, and covers the through hole 112. The first sensor chip 140 is electrically connected to the first processing chip 150a. The second processing chip 160 is disposed in the recess 114 of the substrate 110 and located in the second chamber S2. The second processing chip 160 is air isolated from the first chamber S1. The gel 170a fills the second chamber S2 and at least covers the second processing chip 160.

In an embodiment, the substrate 110 may be a circuit board, e.g., a printed circuit board (PCB), which should however not be construed as a limitation in the disclosure. The package component 120 may be coupled to the upper surface 111 of the substrate 110 through bonding components 125, and the package component 120 and the substrate 110 define the first chamber S1. In an embodiment, a material of the package component 120 may, for instance, include metal materials, such as stainless steel, brass, or copper, which may provide an electromagnetic shielding function, but this should not be construed as a limitation in the disclosure. In an embodiment, a material of the bonding components 125 may, for instance, include conductive metal materials, such as solder ball, solder paste, or solder bump, which should however not be construed as a limitation in the disclosure.

With reference to FIG. 1, in this embodiment, the spacer layer 130a is implemented to have a flat-shaped structure, i.e., a single platform design, and the spacer layer 130a has a top surface 131a facing the first chamber S1 and a bottom surface 133a facing the second chamber S2. The top surface 131a and the bottom surface 133a of the spacer layer 130a are parallel, and a thickness of the spacer layer 130a has a constant value. In this embodiment, the spacer layer 130a is further equipped with an opening 132a which penetrates the top surface 131a and communicates with the second chamber S2. In an embodiment, the opening 132a may be regarded as a gel filling hole, which should however not be construed as a limitation in the disclosure.

Besides, the electronic device 100a provided in this embodiment further includes a plurality of bonding components 190 disposed between the bottom surface 133a of the spacer layer 130a and the upper surface 111 of the substrate 110, where the spacer layer 130a is coupled to the upper surface 111 of the substrate 110 through the bonding components 190. In an embodiment, a material of the bonding components 190 may, for instance, include conductive metal materials, such as solder balls, solder paste, or solder bumps, which should however not be construed as a limitation in the disclosure. In an embodiment, the bonding components 190 may also be adhesives, such as silicone, epoxy resin, and so forth. As shown in FIG. 1, the top surface 131a of the spacer layer 130a provided in this embodiment is higher than the upper surface 111 of the substrate 110, and the upper surface 111 of the substrate 110 is higher than a bottom surface of the recess 114. Here, a material of the spacer layer 130a includes, for instance, ceramics; that is, the spacer layer 130a is a ceramic plate, which should however not be construed as a limitation in the disclosure.

In this embodiment, the first sensor chip 140 is, for instance, disposed on the upper surface 111 of the substrate 110 through an adhesive layer 10 and covers the through hole 112. The first sensor chip 140 may include a diaphragm 141 and a vent hole 143 formed on the diaphragm 141, and external air outside the through hole 112 may circulate through the vent hole 143. In an embodiment, a material of the diaphragm 141 may, for instance, include plastic, such as polytetrafluoroethene (PTFE), polyethylene (PE), polyimide (PI), or polyether ether ketone (PEEK), which should however not be construed as a limitation in the disclosure. In an embodiment, the first sensor chip 140 may further include a back plate 142 equipped with a plurality of through holes, and a material of the back plate 142 may include an appropriate insulating material, which should not be construed as a limitation in the disclosure. In an embodiment, the first sensor chip 140 may be, for instance, a microphone component for sensing pressure changes caused by the vibration of external sound waves, which should however not be construed as a limitation in the disclosure.

In this embodiment, the first processing chip 150a is, for instance, disposed on the upper surface 111 of the substrate 110 through an adhesive layer 20 and adjacent to the first sensor chip 140, and the first processing chip 150a is located in the first chamber S1. The first sensor chip 140 is, for instance, electrically connected to the first processing chip 150a through a solder wire W1, and the first processing chip 150a is, for instance, electrically connected to the substrate 110 through a solder wire W2. In an embodiment, the first processing chip 150a may further include an insulating layer 152 and an internal wiring structure 154, where the insulating layer 152 covers the solder wires W1 and W2, and the internal wiring structure 154 is electrically connected to the solder wires W1 and W2. The insulating layer 152 and the internal wiring structure 154 may be any suitable combination of components applicable to the first processing chip 150a, which should however not be construed as a limitation in the disclosure. In an embodiment, the first processing chip 150a may be an application specific integrated circuit (ASIC) for receiving and processing signals measured by the first sensor chip 140.

In this embodiment, the second processing chip 160 is, for instance, disposed in the recess 114 of the substrate 110 through an adhesive layer 30 and located in the second chamber S2. The second processing chip 160 is, for instance, electrically connected to the substrate 110 through a solder wire W3. Since the second processing chip 160 is located in the second chamber S2 and is air isolated from the first chamber S1, heat generated during the operation of the second processing chip 160 may be isolated in the second chamber S2 and precluded from being transmitted to the first chamber S1 to affect the operation of the first sensor chip 140; namely, thermal interference between the chips may be prevented. In addition, a stress buffering structure may be formed in the substrate 110 by filling the second chamber S2 with the gel 170a, which may enhance the overall rigidity of the substrate 110 and prevent the substrate 110 from being damaged and/or warped during a high-temperature manufacturing process.

Moreover, in this embodiment, the gel 170a, for instance, completely fills the second chamber S2, covers the second processing chip 160 and the solder wire W3, and covers the opening 132a, thereby effectively protecting the second processing chip 160 and the solder wire W3, reducing possible breakage of the solder wire W3 when bonding with the substrate 110, and increasing the structural reliability. In an embodiment, the second chamber S2 may be regarded as a gel filling chamber, which should however not be construed as a limitation in the disclosure. In an embodiment, a material of the gel 170a, for instance, includes thermal management materials, such as phenolic resin, epoxy resin, silicone resin, and so on, which may allow the thermal energy inside the second chamber S2 to be conducted and dissipated through the gel 170a and the substrate 110.

Additionally, the electronic device 100a provided in this embodiment further includes a second sensor chip 180, which is, for instance, disposed on the top surface 131a of the spacer layer 130a through an adhesive layer 40 and located in the first chamber S1. The second sensor chip 180 may be electrically connected to the substrate 110 through a solder wire W4, and the second sensor chip 180 may be electrically connected to the second processing chip 160 through the substrate 110. In an embodiment, the second sensor chip 180 is, for instance, an environmental sensor element for sensing air conditions from the external environment. For instance, the second sensor chip 180 may be a barometer, which should however not be construed as a limitation in the disclosure. In an embodiment, when the second sensor chip 180 is a pressure sensor element, the second sensor chip 180 may have a component (not shown) similar to the diaphragm 141 of the first sensor chip 140 to obtain the required physical quantity through the deformation of the diaphragm together with the pressure. In an embodiment, when the second sensor chip 180 is a temperature sensor element, the second sensor chip 180 may not have any component similar to the diaphragm 141 of the first sensor chip 140, and thus the specific design of the second sensor chip 180 may be determined according to the physical quantity intended to be sensed by the second sensor chip 180 and should not be construed as a limitation in the disclosure. In an embodiment, the second processing chip 160 may be an ASIC for receiving and processing signals measured by the second sensor chip 180.

Besides, the electronic device 100a provided in this embodiment may further include a plurality of conductive components 115 which are separately disposed on the lower surface 113 of the substrate 110 and electrically connected to the substrate 110, the first processing chip 150a, and the second processing chip 160. In an embodiment, the conductive components 115 may be, for instance, electrodes, and a material of the conductive components 115 may, for instance, include solder paste, which should however not be construed as a limitation in the disclosure.

In brief, the package component 120 and the substrate 110 provided in this embodiment define the first chamber S1, while the spacer layer 130a and the recess 114 of the substrate 110 define the second chamber S2. The first sensor chip 140 is located in the first chamber S1, and the second processing chip 160 is located in the second chamber S2 and air isolated from the first chamber S1. Such a design allows the first sensor chip 140 and the second processing chip 160 to be separately positioned in different chambers, potentially reducing interference generated by the second processing chip 160 during operation on the first sensor chip 140. This enables the electronic device 100a provided in this embodiment to achieve improved sensing sensitivity. On the other hand, by adopting the design of the spacer layer 130a and the recess 114 of the substrate 110, different chambers may be constructed for placing different chips, thereby making the most effective use of the limited space inside the chambers.

It should be noted that the following embodiments adopt the reference numbers and some content provided in the previous embodiments, where the same or similar reference numbers serve to denote the same or similar components, and the description of the same technical content is omitted. The description of the omitted parts may be referred to as that provided in the previous embodiments and will not be redundantly repeated in the following embodiments.

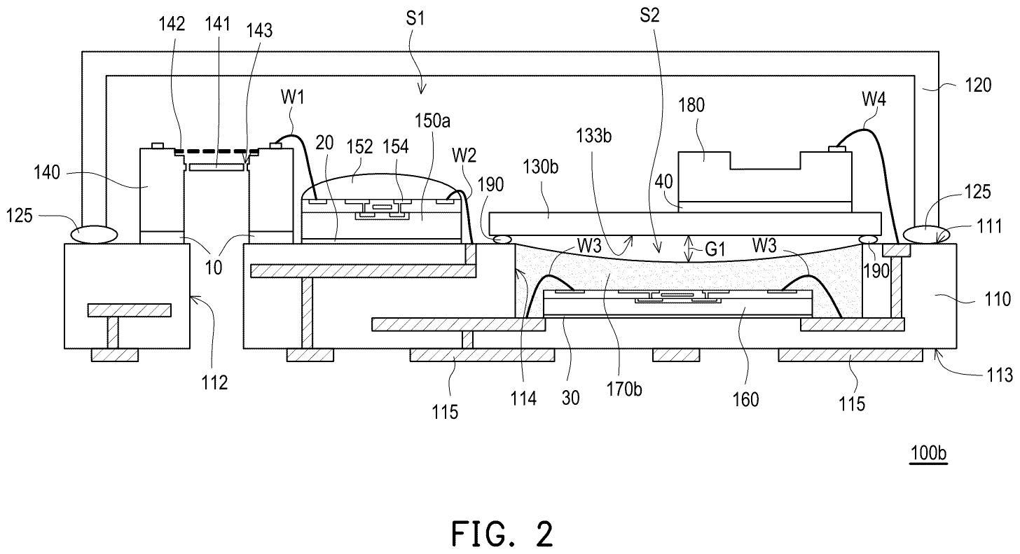

FIG. 2 is a schematic cross-sectional view of an electronic device according to another embodiment of the disclosure. With reference to FIG. 1 and FIG. 2, an electronic device 100b provided in this embodiment is similar to the electronic device 100a, while the main difference therebetween lies in that a spacer layer 130b provided in this embodiment does not have any opening, and a gel 170b does not completely fill the second chamber S2, thus forming a gap G1 between the gel 170b and a bottom surface 133b of the spacer layer 130b, and the gel 170b has a concave arc-shaped cross-sectional profile adjacent to the gap G1, which should however not be construed as a limitation in the disclosure.

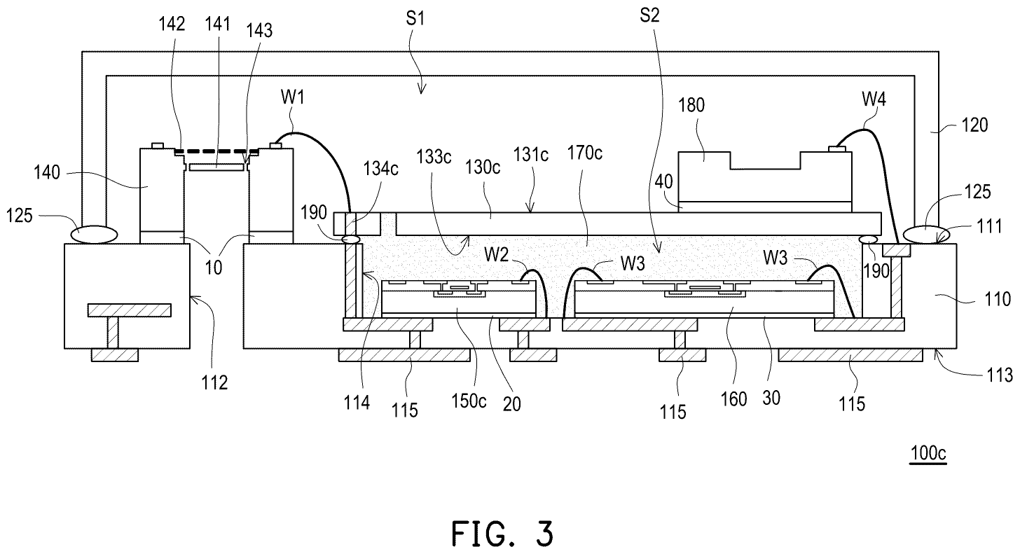

FIG. 3 is a schematic cross-sectional view of an electronic device according to another embodiment of the disclosure. With reference to FIG. 1 and FIG. 3, an electronic device 100c provided in this embodiment is similar to the electronic device 100a, while the main difference therebetween lies in that a first processing chip 150c provided in this embodiment is disposed in the recess 114 of the substrate 110, adjacent to the second processing chip 160, and located in the second chamber S2, where the first processing chip 150c is, for instance, electrically connected to the substrate 110 through the solder wire W2.

Besides, a spacer layer 130c provided in this embodiment may be bonded to the substrate 110 through the bonding components 190 and electrically connected to the substrate 110. In an embodiment, the spacer layer 130c may be, for instance, a PCB, and the material of the bonding components 190 may be conductive metal materials, such as solder balls or solder bumps, which should however not be construed as a limitation in the disclosure. In this embodiment, the spacer layer 130c includes at least one conductive path 134c electrically connecting a top surface 131c to a bottom surface 133c and connecting the solder wire W1 and the bonding components 190, so that the first sensor chip 140 is electrically connected to the first processing chip 150c through the conductive path 134 of the spacer layer 130c, the bonding components 190, and the substrate 110.

In addition, a gel 170c provided in this embodiment not only covers the second processing chip 160 and the solder wire W3 but also covers the first processing chip 150c and the solder wire W2. This may effectively protect the first processing chip 150c, the second processing chip 160, the solder wire W2, and the solder wire W3, potentially reducing the breakage of the solder wire W2 and the solder wire W3 when bonding with the substrate 110, thereby increasing structural reliability.

Since the first processing chip 150c and the second processing chip 160 provided in this embodiment are both disposed in the second chamber S2, while the first sensor chip 140 and the second sensor chip 180 are disposed in the first chamber S1 which is different from the second chamber S2, the interference generated by the first processing chip 150c and the second processing chip 160 during operation on the first sensor chip 140 and the second sensor chip 180 may be effectively reduced, thereby making the electronic device 100c provided in this embodiment to achieve improved sensing sensitivity.

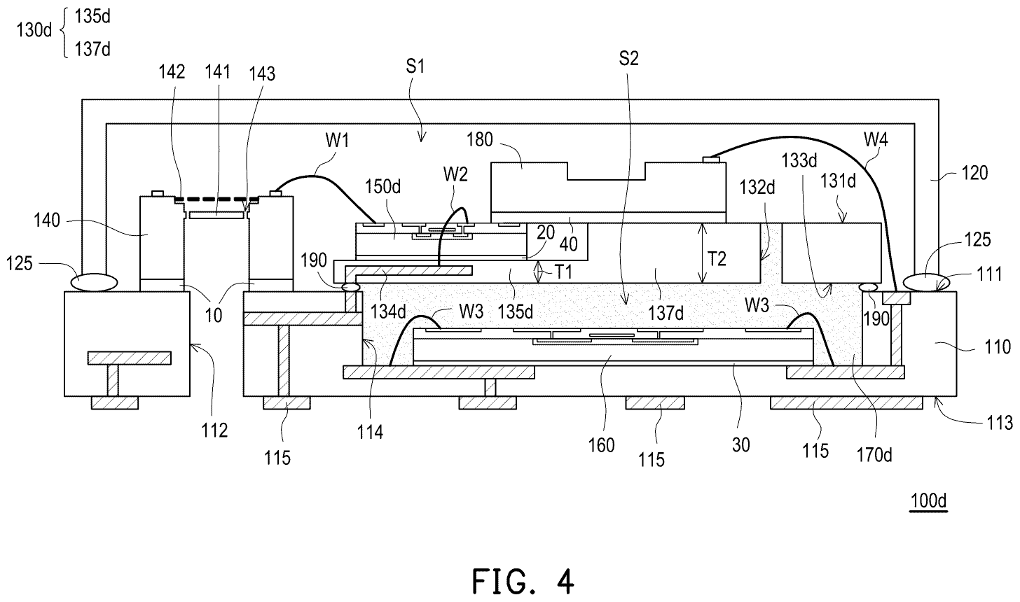

FIG. 4 is a schematic cross-sectional view of an electronic device according to another embodiment of the disclosure. With reference to FIG. 1 and FIG. 4, an electronic device 100d provided in this embodiment is similar to the electronic device 100a, while the main difference therebetween lies in that a spacer layer 130d provided in this embodiment may be bonded to the substrate 110 through the bonding components 190 and electrically connected to the substrate 110. In an embodiment, the spacer layer 130d may be, for instance, a PCB, and the material of the bonding components 190 may, for instance, include conductive metal materials, such as solder balls or solder bumps, which should however not be construed as a limitation in the disclosure.

Specifically, the spacer layer 130d provided in this embodiment includes a first portion 135d with a first thickness T1 and a second portion 137d with a second thickness T2, and the first thickness T1 is less than the second thickness T2. As shown in FIG. 4, the first portion 135d and the second portion 137d jointly define that the spacer layer 130d is in a stepped shape. Besides, the spacer layer 130d provided in this embodiment may include at least one conductive path 134d connecting the bonding components 190. A first processing chip 150d is disposed on the first portion 135d of the spacer layer 130d and adjacent to the first sensor chip 140, and the first processing chip 150d is located within the first chamber S1. The first sensor chip 140 is electrically connected to the first processing chip 150d through, for instance, a solder wire W1, and the first processing chip 150d is electrically connected to the conductive path 134d of the spacer layer 130d through the solder wire W2, for instance, and the conductive path 134d of the spacer layer 130d is electrically connected to the substrate 110 through the bonding components 190. In short, the first sensor chip 140 is electrically connected to the substrate 110 through the spacer layer 130d.

In addition, the second sensor chip 180 provided in this embodiment is disposed on the second portion 137d of the spacer layer 130d and located in the first chamber S1. A portion of the second sensor chip 180 is stacked on the first processing chip 150d, the second sensor chip 180 is electrically connected to the substrate 110 through a solder wire W4, for instance, and the second sensor chip 180 is electrically connected to the second processing chip 160 through the substrate 110. In other words, the second sensor chip 180 provided in this embodiment is structurally connected to the first processing chip 150d but not electrically connected to the first processing chip 150d. Moreover, the second portion 137d of the spacer layer 130d in this embodiment has an opening 132d, and a gel 170d completely fills the second chamber S2 and covers the opening 132d.

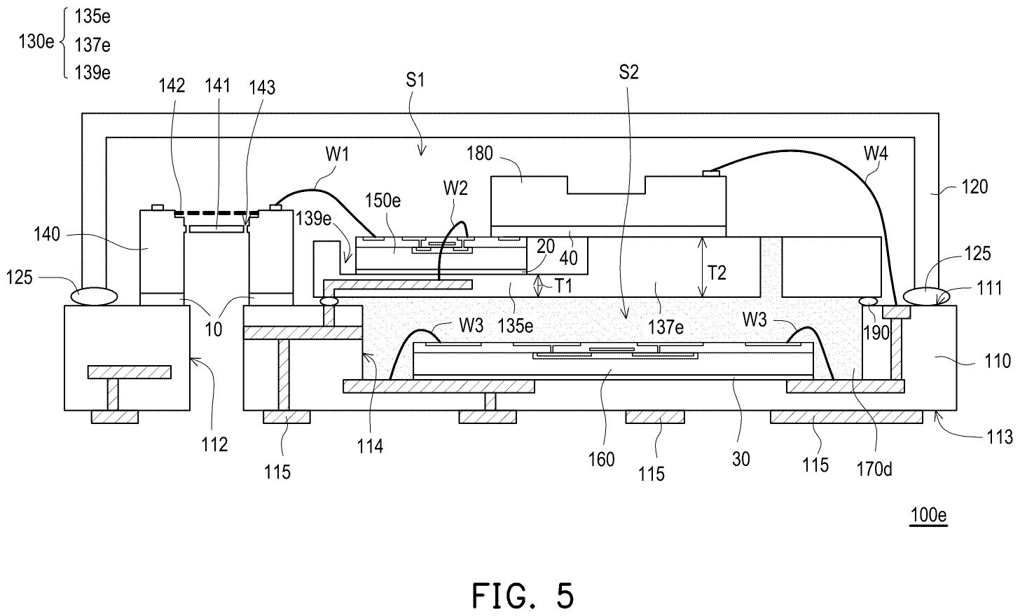

FIG. 5 is a schematic cross-sectional view of an electronic device according to another embodiment of the disclosure. With reference to FIG. 4 and FIG. 5, an electronic device 100e provided in this embodiment is similar to the electronic device 100d, while the main difference therebetween lies in that a second portion 137e provided in this embodiment surrounds a first portion 135e, the first portion 135e and the second portion 137e jointly form a recess 139e of the spacer layer 130e, and the first processing chip 150e is disposed in the recess 139e of the spacer layer 130e.

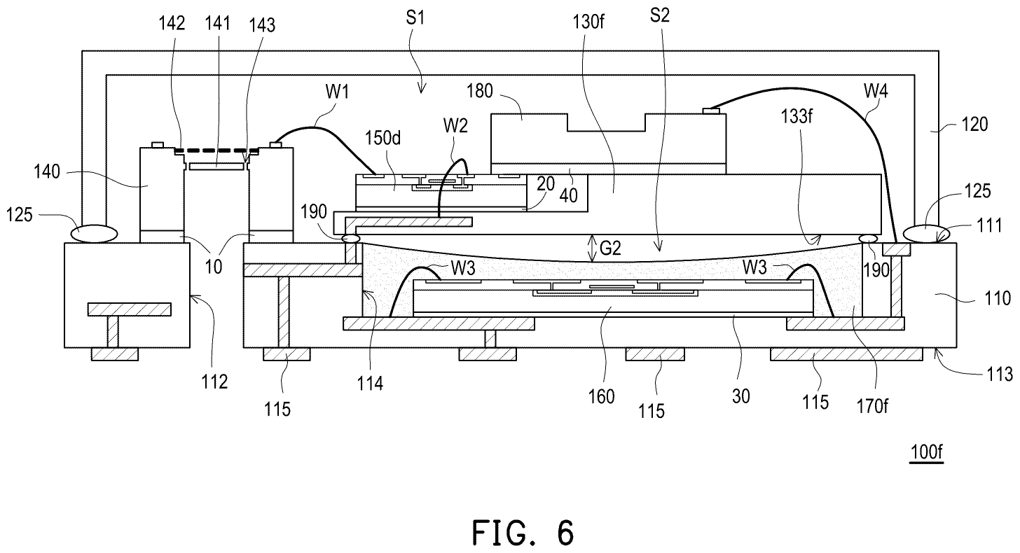

FIG. 6 is a schematic cross-sectional view of an electronic device according to another embodiment of the disclosure. With reference to FIG. 4 and FIG. 6, an electronic device 100f provided in this embodiment is similar to the electronic device 100d, while the main difference therebetween lies in that a spacer layer 130f provided in this embodiment does not have any opening, and a gel 170f does not completely fill the second chamber S2, thus forming a gap G2 between the gel 170f and a bottom surface 133f of the spacer layer 130f. In an embodiment, the gel 170f has a concave arc-shaped cross-sectional profile adjacent to the gap G2, for instance, which should however not be construed as a limitation in the disclosure.

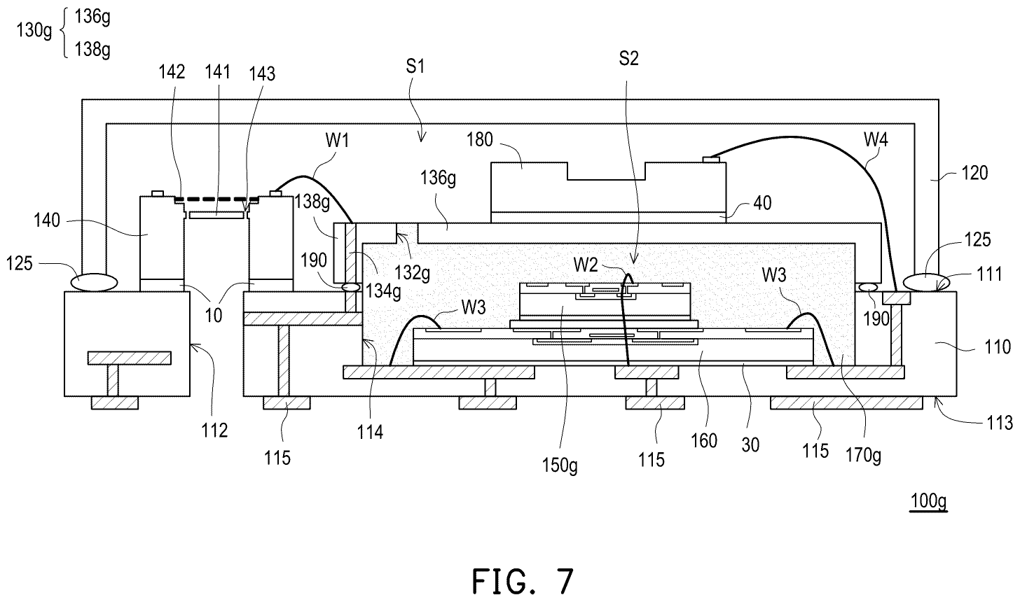

FIG. 7 is a schematic cross-sectional view of an electronic device according to another embodiment of the disclosure. With reference to FIG. 1 and FIG. 7, an electronic device 100g provided in this embodiment is similar to the electronic device 100a, while the main difference therebetween lies in that a spacer layer 130g provided in this embodiment may be bonded to the substrate 110 through the bonding components 190 and electrically connected to the substrate 110. In an embodiment, the spacer layer 130g may be, for instance, a PCB, and the material of the bonding components 190 may, for instance, include conductive metal materials, such as solder balls or solder bumps, which should however not be construed as a limitation in the disclosure.

In detail, the spacer layer 130g provided in this embodiment includes a top portion 136g and a side portion 138g vertically connected to peripheries of the top portion 136g, and the top portion 136g and the side portion 138g jointly define that the spacer layer 130g is in an inverted U shape. The top portion 136g of the spacer layer 130g further has an opening 132g, and the opening 132g communicates with the second chamber S2. The spacer layer 130g provided in this embodiment may include at least one conductive path 134g connecting the solder wire W1 and the bonding components 190. The first sensor chip 140 is electrically connected to the substrate 110 through the spacer layer 130g. The first processing chip 150g is disposed in the recess 114 of the substrate 110, stacked on the second processing chip 160, and located in the second chamber S2. The first processing chip 150g is electrically connected to the substrate 110 through the solder wire W2, for instance, and the gel 170g completely fills the second chamber S2, covers the second processing chip 160, the first processing chip 150g, the solder wire W2, and the solder wire W1, and covers the opening 132g. The second sensor chip 180 is disposed on the top portion 136g of the spacer layer 130g and electrically connected to the substrate 110 through the solder wire W4, for instance.

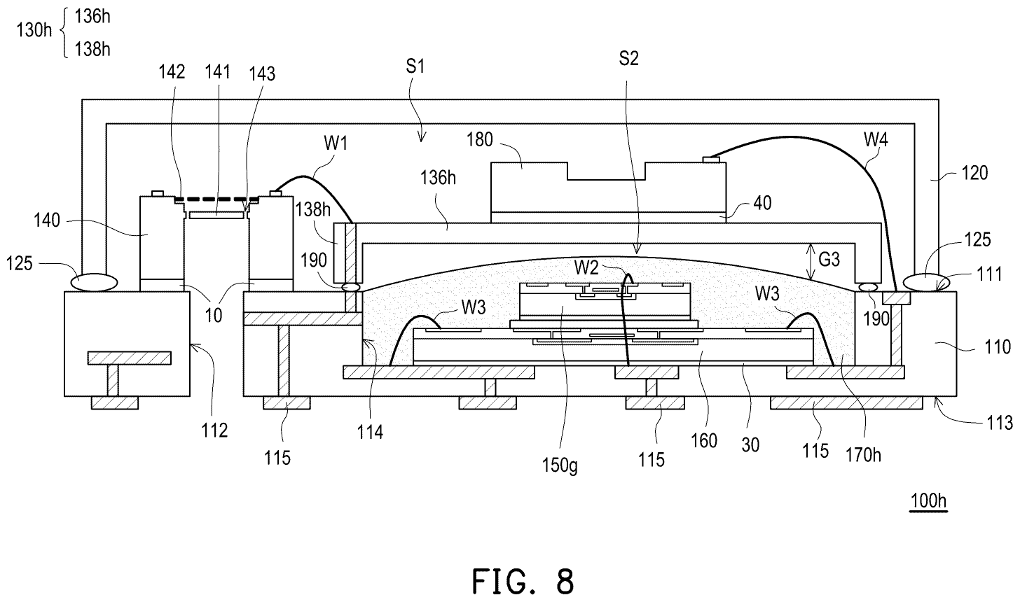

FIG. 8 is a schematic cross-sectional view of an electronic device according to another embodiment of the disclosure. With reference to FIG. 7 and FIG. 8, an electronic device 100h provided in this embodiment is similar to the electronic device 100g, while the main difference therebetween lies in that a spacer layer 130h provided in this embodiment includes a top portion 136h and a side portion 138h but does not have any opening, and a gel 170h does not completely fill the second chamber S2, thus forming a gap G3 between the gel 170h and the top portion 136h. In an embodiment, the gel 170h has a convex arc-shaped cross-sectional profile adjacent to the gap G3, for instance, which should however not be construed as a limitation in the disclosure.

To sum up, according to the design of the electronic device provided in one or more embodiments of the disclosure, the package component and the substrate define the first chamber, and the spacer layer and the recess of the substrate define the second chamber, where the first sensor chip is located in the first chamber, and the second processing chip is located in the second chamber and is air isolated from the first chamber. With this design, the sensor chip and the processing chip can be separately disposed in different chambers to reduce the interference caused by the processing chip to the sensor chip during operation, thereby allowing the electronic device provided in one or more embodiments of the disclosure to have an improved sensor sensitivity. On the other hand, the design of the spacer layer and the recess of the substrate allows construction of different chambers where different chips may be placed, thereby optimally utilizing the limited space inside the chambers.

It will be apparent to those skilled in the art that various modifications and variations may be made to the disclosed embodiments without departing from the scope or spirit of the disclosure. In view of the foregoing, it is intended that the disclosure covers modifications and variations provided they fall within the scope of the following claims and their equivalents.

What is claimed is:

1. An electronic device, comprising:
a substrate, having a first upper surface and a lower surface opposite to each other, a through hole penetrating the substrate and connecting the upper surface and the lower surface, and a recess extending from the upper surface to the lower surface;
a package component, disposed on the upper surface of the substrate, the package component and the substrate defining a first chamber;
a spacer layer, disposed on the upper surface of the substrate and covering the recess, the spacer layer and the recess defining a second chamber;
a first sensor chip, disposed on the upper surface of the substrate, located in the first chamber, and covering the through hole, wherein the first sensor chip is electrically connected to a first processing chip;
a second processing chip, disposed in the recess of the substrate and located in the second chamber, wherein the second processing chip is air isolated from the first chamber; and
a gel, filling the second chamber and at least covering the second processing chip.

2. The electronic device according to claim 1, wherein the first processing chip is disposed on the upper surface of the substrate and adjacent to the first sensor chip and located in the first chamber.

3. The electronic device according to claim 1, wherein the first processing chip is disposed in the recess of the substrate and adjacent to the second processing chip and located in the second chamber, and the gel further covers the first processing chip.

4. The electronic device according to claim 1, wherein the spacer layer has a flat-shaped structure, a top surface facing the first chamber, and a bottom surface facing the second chamber.

5. The electronic device according to claim 4, further comprising:
a second sensor chip, disposed on the top surface, located in the first chamber, and electrically connected to the second processing chip through the substrate.

6. The electronic device according to claim 4, wherein the spacer layer further has an opening, and the gel completely fills the second chamber and covers the opening.

7. The electronic device according to claim 4, wherein the gel does not completely fill the second chamber, so that a gap is formed between the gel and the bottom surface, and the gel has a concave arc-shaped cross-sectional profile adjacent to the gap.

8. The electronic device according to claim 1, wherein the spacer layer comprises a first portion having a first thickness and a second portion having a second thickness, and the first thickness is less than the second thickness.

9. The electronic device according to claim 8, wherein the first processing chip is disposed on the first portion of the spacer layer and adjacent to the first sensor chip and located in the first chamber, and the first sensor chip is electrically connected to the substrate through the spacer layer.

10. The electronic device according to claim 9, further comprising:
a second sensor chip, disposed on the second portion of the spacer layer and located in the first chamber, wherein a portion of the second sensor chip is stacked on the first processing chip, and the second sensor chip is electrically connected to the second processing chip through the substrate.

11. The electronic device according to claim 8, wherein the first portion and the second portion jointly define that the spacer layer is in a stepped shape.

12. The electronic device according to claim 8, wherein the second portion surrounds the first portion, and the second portion and the first portion jointly form a recess of the spacer layer.

13. The electronic device according to claim 8, wherein the second portion further has an opening, and the gel completely fills the second chamber and covers the opening.

14. The electronic device according to claim 1, wherein the first processing chip is disposed in the recess of the substrate, stacked on the second processing chip, and located in the second chamber.

15. The electronic device according to claim 14, wherein the spacer layer comprises a top portion and a side portion vertically connected to peripheries of the top portion, and the top portion and the side portion jointly define that the spacer layer is in an inverted U shape.

16. The electronic device according to claim 15, wherein the top portion further has an opening, and the gel completely fills the second chamber and covers the opening and the first processing chip.

17. The electronic device according to claim 15, wherein the gel does not completely fill the second chamber, so that a gap is formed between the gel and the top portion, and the gel has a convex arc-shaped cross-sectional profile adjacent to the gap.

18. The electronic device according to claim 1, further comprising:
a plurality of bonding components, disposed between the spacer layer and the upper surface of the substrate, wherein the spacer layer is bonded to the substrate through the bonding components and is electrically connected to the substrate.

19. The electronic device according to claim 1, wherein the spacer layer comprises at least one conductive path, and the first sensor chip is electrically connected to the first processing chip through the at least one conductive path of the spacer layer.

20. The electronic device according to claim 1, further comprising:
a plurality of conductive components, disposed on the lower surface of the substrate and electrically connected to the first processing chip and the second processing chip.
